(19) United States
(12) Patent Application Publication
(10) Pub. No.: US 2016/0174362 A1
(43) Pub. Date: Jun. 16, 2016

(54) APPARATUS, SYSTEM AND METHOD TO PROTECT SIGNAL COMMUNICATION INTEGRITY

(71) Applicants: Kevin J. Doran, North Plains, OR (US); Stephen H. Hall, Forest Grove, OR (US); Thomas D. Whiteley, Forest Grove, OR (US); Kai Xiao, University Place, WA (US); Yuan-Liang Li, Taipei (TW); Jimmy Hsu, Taoyuan (TW); Thonas Yi-Ren Su, Taipei (TW)

(72) Inventors: Kevin J. Doran, North Plains, OR (US); Stephen H. Hall, Forest Grove, OR (US); Thomas D. Whiteley, Forest Grove, OR (US); Kai Xiao, University Place, WA (US); Yuan-Liang Li, Taipei (TW); Jimmy Hsu, Taoyuan (TW); Thonas Yi-Ren Su, Taipei (TW)

(21) Appl. No.: 14/569,524

(22) Filed: Dec. 12, 2014

(51) Int. Cl. H05K 1/02; H05K 3/40; H05K 1/18; H05K 3/10

(52) U.S. Cl. CPC H05K 1/0216; H05K 3/10; H05K 3/40; H05K 1/18

(57) ABSTRACT

Techniques and mechanisms to mitigate noise in a signal line extending across rails arranged in a split plane configuration. In an embodiment, respective sides of a first rail and a second rail define opposite sides of a boundary region between the rails. The first rail forms a groove and the second rail forms a branch portion that extends at least in part into the groove. In another embodiment, one or more signal lines each extend across the boundary region and proximate to the branch portion, the one or more signals each to communicate a respective signal while the first rail is at a first voltage and while the second rail is at a second voltage. The branch portion and groove contribute to a reduced impedance discontinuity across the boundary region, which mitigates the creation of signal noise in the one or more signal lines.

### BACKGROUND

1. Technical Field

Embodiments of the invention generally relate to the field of circuit design and more particularly, but not exclusively, to mitigation of signal noise.

2. Background Art

A printed circuit board (PCB) is one example of circuit hardware that typically has multiple power and/or ground rails. A “split plane” refers to an instance of a small separation between two such rails. A voltage difference between the two rails will excite the split, which in turn can induce the generation of noise in signal lines proximate to the split. In the case of a signal trace carrying current across a split plane, the split will add to impedance mismatch and/or increase crosstalk between neighboring traces, adding to impedance mismatch and/or increasing crosstalk between neighboring traces.

A conventional technique to reduce such loss in signal integrity is to avoid trace layouts that cross a split plane and/or to run traces in parallel to any split plane. However, this imposes a significant burden on PCB and/or integrated circuit (IC) design flexibility. This burden in turn leads to increased motherboard and package layers, higher bill of material (BOM) cost, greater design complexity and increased platform height.

As successive generations of integrated circuitry continue to scale in terms of size, speed, voltage, etc. there is an attendant demand for the platforms in which such circuitry operates to support high bit-rate, power efficient signaling. The need for mechanisms to reduce sources of signal noise is one aspect of this demand.

### BRIEF DESCRIPTION OF THE DRAWINGS

The various embodiments of the present invention are illustrated by way of example, and not by way of limitation, in the figures of the accompanying drawings and in which:

FIG. 1 is a high-level block diagram illustrating elements of a system including structures to mitigate loss of signal integrity according to an embodiment.

FIG. 2 is a detail view of a device including structures to mitigate signal integrity loss according to an embodiment.

FIGS. 3A-3D are detail views each illustrating features of devices including respective structures to variously mitigate signal noise each according to a corresponding embodiment.

FIGS. 4A-4C are detail views each illustrating features of devices including respective structures to variously mitigate signal noise each according to a corresponding embodiment.

FIGS. 5A-5D are detail views each illustrating features of devices including respective structures to variously mitigate signal noise each according to a corresponding embodiment.

FIG. 6 is a flow diagram illustrating elements of a method to fabricate a device to exchange signal communications according to an embodiment.

FIGS. 7A, 7B are detail views each illustrating features of respective structures to mitigate signal integrity loss according to a corresponding embodiment.

FIG. 7C is a table including examples of dimensions for respective devices shown in FIGS. 7A, 7B.

FIG. 8 is a block diagram illustrating elements of a computing system for communicating signals protected according to an embodiment.

FIG. 9 is a block diagram illustrating elements of a mobile device for communicating signals protected according to an embodiment.

### DETAILED DESCRIPTION

Embodiments discussed herein variously provide techniques and/or mechanisms for the mitigation of noise in signals communicated over a substrate such as that of the printed circuit board or a packaged IC device. One result of structures such as those discussed herein is that high-speed buses or other signal lines, such as those of a dual data rate (DDR) device, may be more easily routed over a split plane—e.g., reducing the need for extra PCB or package layers, decreasing design complexity and/or reducing BOM cost. In addition to enabling a motherboard or other PCB to be smaller in size, certain embodiments enable a total number of layers of a system-on-chip (SOC) or other integrated circuit (IC) package to decrease. Alternatively or in addition, embodiments may allow for a reduction in the need for surface-mounted decoupling capacitors across split rails.

Signal noise mitigation structures discussed herein variously provide for a relative increase to an amount of capacitance that a signal experiences as it propagates in a trace across a split plane boundary region. An impedance discontinuity (Z_{D}) across a split plane boundary region may be represented by the following equation:

$${Z}_{D} = \frac{1}{j ω C} , \qquad ( 1 )$$

where j is the square root of −1, ω is a signal corner frequency, and C is a capacitance between two rails defining the split plane boundary region. In a simple scenario of straight rails having respective flat sides separated from one another by a distance D, the capacitance C may be represented with the following equation:

$$C = \frac{{ε}_{r} {ε}_{o} A}{D} . \qquad ( 2 )$$

where ε₀ is the permittivity of empty space, εᵣ is a relative dielectric constant of a material between the rails, and A is an area of capacitive coupling between the rails. Combining the equations (1) and (2) above yields the following:

$${Z}_{D} = \frac{D}{j ω {ε}_{r} {ε}_{o} A} . \qquad ( 3 )$$

Certain embodiments are a result of a realization that, for various scenarios, as the coupled area between rails becomes larger, the impact of signal noise in nearby traces due to impedance discontinuity Z_{D} becomes smaller. These embodiments provide a low-cost, effective method to reduce the impact of noise that might otherwise be induced by a split plane in one or more signal lines such as those in or on a PCB.

Reduction of a coupled area between rails of a split plane arrangement may be implemented without additional circuit elements or other such components. Providing interleaved rail structures according to an embodiment allows for capacitive manipulation to improve signal integrity by reducing signal distortion such as that due to electro-magnetic reflection.

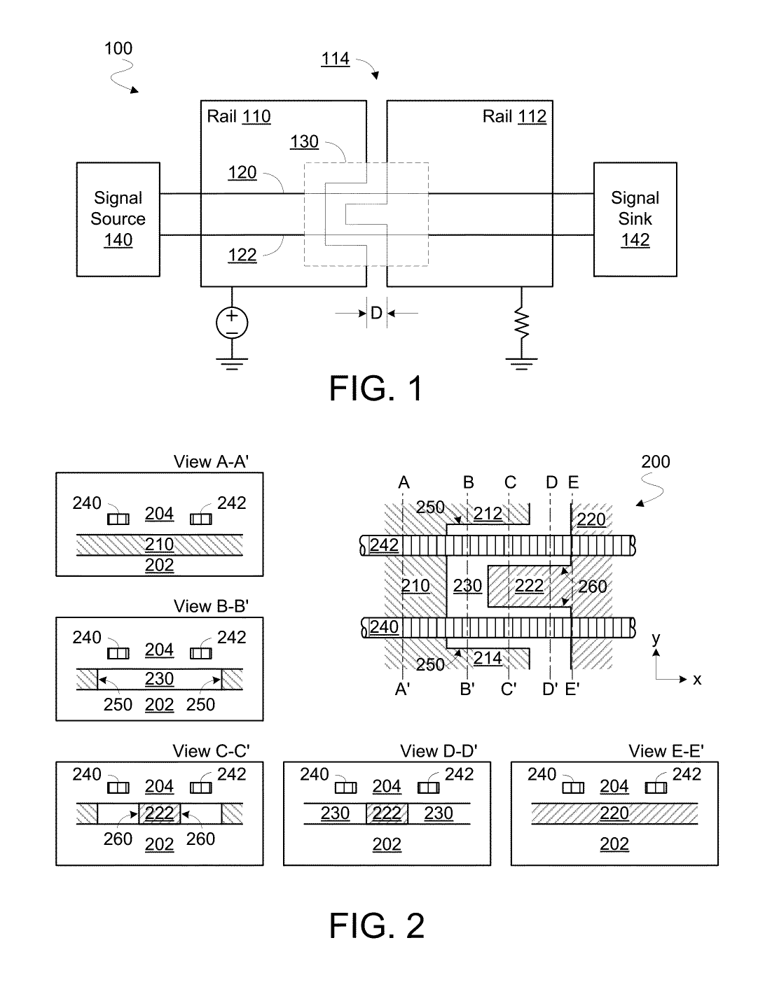

FIG. 1 illustrates elements of a system 100 to exchange signals according to an embodiment. Non-limiting examples of systems such as system 100 that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any electronic device that is to exchange signals via one or more signal lines that extend across a boundary region between rails arranged in a split plane configuration. Certain embodiments are discussed herein with respect to mitigating signal noise in multiple signal lines such as those for communicating a differential signal pair. However, certain embodiments are not limited in this regard, and may additionally or alternatively relate, for example, noise mitigation in one or more single-ended signal lines.

System 100 may include a signal source 140 coupled to a signal sink 142 via one or more signal lines—e.g., as represented by the illustrative traces 120, 122. Signal source 140 and signal sink 142 may each be any of a variety of integrated circuits, packaged devices, or other components that are configured to exchange signals. By way of illustration and not limitation, such components may include processor logic (such as a central processing unit, processor core, or the like), controller logic (such as a memory controller, microcontroller, etc.), a hub device, bus driver circuitry, a memory module or other memory device, etc. The particular type of source and/or sink of communicating via one or both of traces 120, 122 may not be limiting on certain embodiments. Signal source 140 and signal sink 142 may reside in different packaged devices that are coupled to a motherboard or other PCB of system 100. Alternatively, signal source 140 and signal sink 142 may be different functional blocks of the same integrated circuit die or packaged device. Signal source 140 may transmit signals to signal sink 142 via traces 120, 122. In some embodiments, signal source 140 may further serve as a sink for other signals transmitted from signal sink 142 via traces 120, 122 or one or more other signal lines (not shown).

System 100 may include rails that are each to be maintained at a respective voltage level during operation of system 100. By way of illustration and not limitation, rails 110, 112 of system 100 may function to provide, respectively, a supply potential and a reference potential (e.g., ground) to facilitate operation of one or more components of system 100. Alternatively, rails 110, 112 of system 100 may function to provide different (or the same) supply voltage levels. The particular voltage levels provided by rails 110, 112 and/or the particular components of system 100 to receive one or both such voltage levels are not limiting on certain embodiments.

A region 114 (referred to herein as a boundary region) may separate rails 110, 112 from one another—e.g., where signals 120, 122 extend across a plane that is orthogonal to respective surfaces of rails 110, 112 and that extends through at least part of region 114. By way of illustration and not limitation, rails 110, 112 may each comprise a conductive material (e.g., copper) forming a respective sheet, trace or other structure that resides in a metallization layer of system 100. Rails 110, 112, may extend across a surface of that metallization layer at least in a region that is proximate to region 114.

To reduce the possibility of signal noise being generated in one or both of traces 120, 122, certain embodiments provide one or more structures 130 formed at least in part by respective sides of rails 110, 112 that adjoin 114. The one or more structures 130 may prevent at least some signal noise by contributing to a reduction in impedance discontinuity Z_{D} across region 114. The reduction in Z_{D} may be achieved by decreasing a ratio of a separation distance D between rails 110, 112 to a capacitive coupled area of region 114. In an embodiment, the one or more structures 130 include a branch portion of one of rails 110, 112 extending into a groove portion formed by the other of rails 110, 112. For example, portions of rail 110 may be interleaved with one or more other portions of rail 112. The particular structures 130 shown are merely illustrative of one embodiment.

FIG. 2 illustrates elements of a device 200 including structures to mitigate signal noise according to an embodiment. Device 200 may include some or all of the features of system 100, for example.

In an embodiment, device 200 includes rails 210, 220 and traces 240, 242 that extend across—e.g. above (or below) and proximate to—a region 230 between rails 210, 220. For example, traces 240, 242 may each be one of traces 120, 122, and/or rails 210, 220 may each be one of rails 110, 112. A side 250 of rail 210 and a side 260 of rail 220 may adjoin and define at least in part opposite sides of region 230, where sides 250, 260 variously form at least in part respective structures to aid in the prevention of signal noise that might otherwise be induced in one or both of traces 240, 242. Details of such structures are variously represented in cross-section by views A-A′, B-B′, C-C′, D-D′ and E-E′ of FIG. 2.

As shown in these views, rails 210, 220 may be disposed directly or indirectly on a substrate layer 202 (e.g., including a PCB substrate material or a semiconductor substrate material). In one embodiment, rails 210, 220 are disposed on any of a variety of conventional insulative materials including, but not limited to, glass (e.g., fiberglass), plastic, silicon nitride (SiN), or the like. Rails 240, 242 may be separated from rails 210, 220 in a layer 204 including any of various insulative materials. In an embodiment an insulative material is disposed in region 230—e.g., where such insulative material is contiguous with one or both of layers 202, 204.

In the illustrative embodiment of device 200, a portion of side 260 extends away from the E-E′ cross-sectional plane and along a direction in an x-axis toward rail 210. This results at least in part in the formation of a branch portion 222 of rail 220. Alternatively or in addition, a portion of side 250 may also extend along the x-axis, in a direction away from the E-E′ cross-sectional plane, to form a groove. Portion 212, 214 of rail 210 may define sidewalls of such a groove—e.g., where branch portion 222 extends at least in part into the groove and between the respective sidewalls formed by portions 212, 214.

Formation of branch portion 222 and the groove of rail 210 provides for an increased ratio of a capacitively coupled area of region 230 to a distance between rails 210, 220. In turn, this may result in an amount of signal noise in one or both of traces 240, 242 being smaller than might otherwise be generated due to an impedance discontinuity Z_{D} resulting from the split plane configuration of rails 210, 220. In device 200, at least part of branch portion 222 may be located along a y-axis between traces 240, 242—e.g., where traces 240, 242 do not overlap branch portion 222 and/or where traces 240, 242 do not overlap the sidewalls of the groove formed by side 250. However, any of a variety of other shapes and/or relative configurations of branch portions, grooves and/or traces with respect to one another may be provided according to different embodiments.

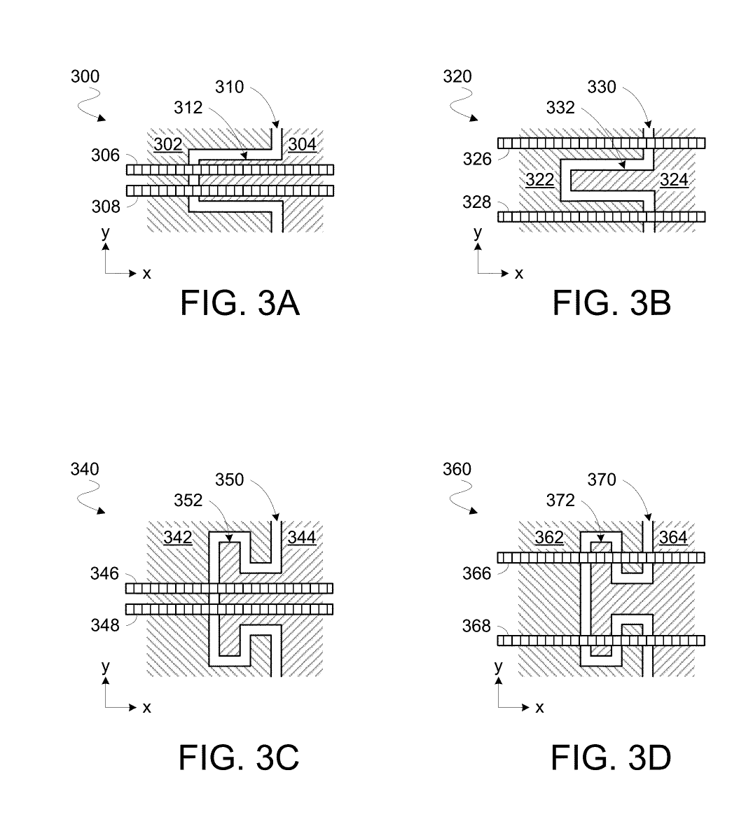

FIG. 3A illustrates elements of a device 300 including structures to mitigate signal noise according to an embodiment. Device 300 may include some or all of the features of system 100, for example. In an embodiment, device 300 includes rails 302, 304 and traces 306, 308 that extend across a region 310 between rails 302, 304.

Device 300 may include structures to aid in the prevention of signal noise that might otherwise be induced in one or both of traces 306, 306 by the split plane arrangement of rails 302, 304. By way of illustration and not limitation, a branch portion 312 of rail 304 may extend along an x-axis direction toward rail 302 and at least partially into a groove formed by a side of rail 302 that adjoins region 310. Branch portion 312 (and the associated groove of rail 302) may provide for an increased area of region 310—e.g., relative to a separation distance between rails 302, 304.

The arrangement of branch-grove structures of device 300 may have some or all of the features of the arrangement of branch-grove structures of device 200, for example. However, device 300 may vary from device 200 at least with respect to a configuration of traces 306, 308 relative to such branch-grove structures. For example, one of both of traces 306, 308 may at least partially overlap branch portion 312 along the y-axis shown.

Certain embodiments allow a board designer or chip designer to choose—e.g., based on noise reduction characteristics—a preferred relative configuration of some or all of traces 306, 308, branch portion 312 and the corresponding groove of rail 302. For example, possible parameters for design-time evaluation of signal propagation, reflection, etc. may include one or more of a degree of overlap (if any) of branch portion 312 and one or each of traces 306, 308, a degree of offset between branch portion 312 and one or each of traces 306, 308, and a degree of offset between one or each of traces 306, 308 and the sides of the groove of rail 302.

FIG. 3B illustrates elements of a device 320 including structures to mitigate signal noise according to another embodiment. Device 320 may include some or all of the features of system 100, for example. In an embodiment, device 320 includes rails 322, 324 and traces 326, 328 that extend across a region 330 between rails 322, 324. A branch portion 332 of rail 324 may extend along an x-axis direction toward rail 322 and at least partially into a groove formed by a side of rail 322 that adjoins region 330. The arrangement of branch-grove structures of device 320 may have some or all of the features of the arrangement of branch-grove structures of device 200 or device 300, for example. However, device 320 varies from devices 200, 300 at least with respect to a configuration of traces 326, 328 relative to such branch-grove structures. More particularly, one of both of traces 326, 328 may extend past region 330 without overlapping, in the y-axis, either branch portion 332 or the associated groove formed by rail 322.

FIG. 3C illustrates elements of a device 340 including structures to mitigate signal noise according to another embodiment. Device 340 may include some or all of the features of system 100, for example. In an embodiment, device 340 includes rails 342, 344 and traces 346, 348 that extend across a region 350 separating rails 342, 344 from one another. To provide at least in part for signal noise mitigation, a branch portion 352 of rail 344 may extend along an x-axis direction toward rail 342 and at least partially into a groove formed by a side of rail 342 that adjoins region 350.

In an embodiment, branch portion 352 includes a rectilinear or curved T-shape structure—e.g., including a primary branch sub-portion that extends along the x-axis direction, and secondary branch sub-portions that each extend along a respective y-axis direction from a distal end of the primary branch sub-portion. The groove of rail 342 in which branch portion 352 is disposed may have a topology that conforms at least in part to some or all edges of branch portion 352.

An increased area of region 350 provided by branch portion 352 (and the corresponding groove) may support mitigation of signal noise in one or both of traces 346, 348 that extend across and are proximate to region 350 and the groove. In an embodiment, one or both of traces 346, 348 overlap branch portion 352—e.g., where traces 346, 348 extend over the primary branch sub-portion, but not the secondary branch sub-portions. However, the shape of branch portion 352 and/or the configuration of branch portion 352 relative to traces 346, 348 may vary according to different embodiments.

FIG. 3D illustrates elements of a device 360 including structures to mitigate signal noise according to another embodiment. Device 360 may include some or all of the features of system 100, for example. In an embodiment, device 360 includes rails 362, 364 and traces 366, 368 that extend across a region 370 separating rails 362, 364 from one another. A branch portion 372 of rail 364 may extend along an x-axis direction toward rail 362 and at least partially into a groove formed by a side of rail 362 that adjoins region 370. The arrangement of branch-grove structures of device 360 may have some or all of the features of the arrangement of branch-grove structures of device 340—e.g., where branch portion 372 includes a T-shape structure such as that of branch portion 352. However, device 360 may vary from device 340 at least with respect to a configuration of traces 366, 368 relative to such branch-grove structures. For example, one of both of traces 366, 368 may each at least partially overlap a respective secondary branch sub-portion of branch portion 372. Additionally or alternatively, one of both of traces 366, 368 may each overlap a respective portion of rail 362 that is disposed between a secondary branch sub-portion of branch portion 372 and a main portion of rail 364 (from which branch portion 372 extends).

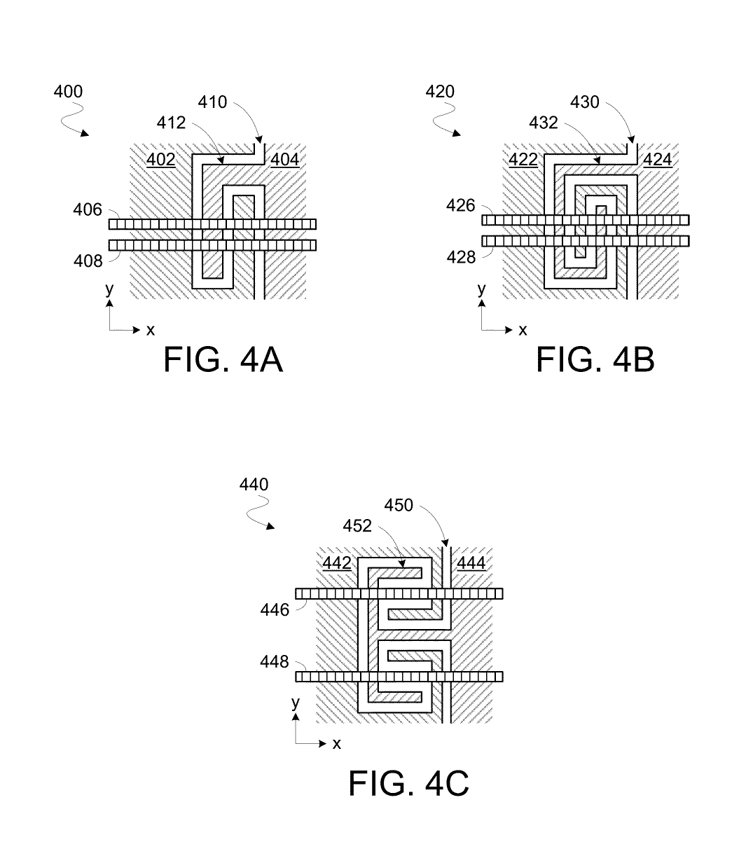

FIG. 4A illustrates elements of a device 400 including structures to mitigate signal noise according to another embodiment. Device 400 may include some or all of the features of system 100, for example. In an embodiment, device 400 includes rails 402, 404 and traces 406, 408 that extend across a region 410 separating rails 402, 404 from one another. A branch portion 412 of rail 404 may extend along an x-axis direction toward rail 402 and at least partially into a groove formed by a side of rail 402 that adjoins region 410.

In an embodiment, branch portion 412 includes a rectilinear and/or curved L-shape structure that extends along the x-axis direction and bends, curves or otherwise changes direction to extend at least in part along a y-axis direction. The groove of rail 402 in which branch portion 412 is disposed may conform at least in part to some or all edges of branch portion 412. An increased area of region 410 provided by branch portion 412 (and by the corresponding groove of rail 402) may support mitigation of signal noise in one or both of traces 406, 408 that extend across and are proximate to region 410 and the groove. In an embodiment, one of both of traces 406, 408 may each at least partially overlap branch portion 412. Additionally or alternatively, one of both of traces 406, 408 may overlap along the y-axis a portion of rail 402 that is disposed between the part of branch portion 412 and a main portion of rail 404 (from which branch portion 412 extends).

FIG. 4B illustrates elements of a device 420 including structures to mitigate signal noise according to another embodiment. Device 420 may include some or all of the features of system 100, for example. In an embodiment, device 420 includes rails 422, 424 and traces 426, 428 that extend across a region 430 separating rails 422, 424 from one another. A branch portion 432 of rail 424 may extend along an x-axis direction toward rail 422 and at least partially into a groove formed by a side of rail 422 that adjoins region 430. Branch portion 432 may include a rectilinear and/or curved spiral structure—e.g., where the groove of rail 422 in which branch portion 432 is disposed may conform at least in part to some or all edges of branch portion 432. In an embodiment, one of both of traces 426, 428 each overlap multiple distinct portions of branch portion 412 that, for example, are joined by other portions of branch 412 that are not overlapped by one or either of traces 426, 428. Additionally or alternatively, one of both of traces 426, 428 may similarly overlap multiple distinct portions of rail 422 that are variously disposed between some part of branch portion 432 and a main portion of rail 424 (from which branch portion 432 extends).

FIG. 4C illustrates elements of a device 440 including structures to mitigate signal noise according to another embodiment. Device 440 may include some or all of the features of system 100, for example. In an embodiment, device 440 includes rails 442, 444 and traces 446, 448 that extend across a region 450 separating rails 442, 444 from one another. A branch portion 452 of rail 444 may extend along an x-axis direction toward rail 442 and at least partially into a groove formed by a side of rail 442 that adjoins region 450. Branch portion 452 may include multiple rectilinear and/or curved spiral structures—e.g., where the groove of rail 442 in which branch portion 452 is disposed may conform at least in part to some or all edges of branch portion 452. In an embodiment, one of both of traces 446, 448 each at least partially overlap branch portion 452. Additionally or alternatively, one of both of traces 446, 448 may each overlap a respective portion of rail 442 that is disposed between a part of branch portion 452 and a main portion of rail 444 (from which branch portion 452 extends).

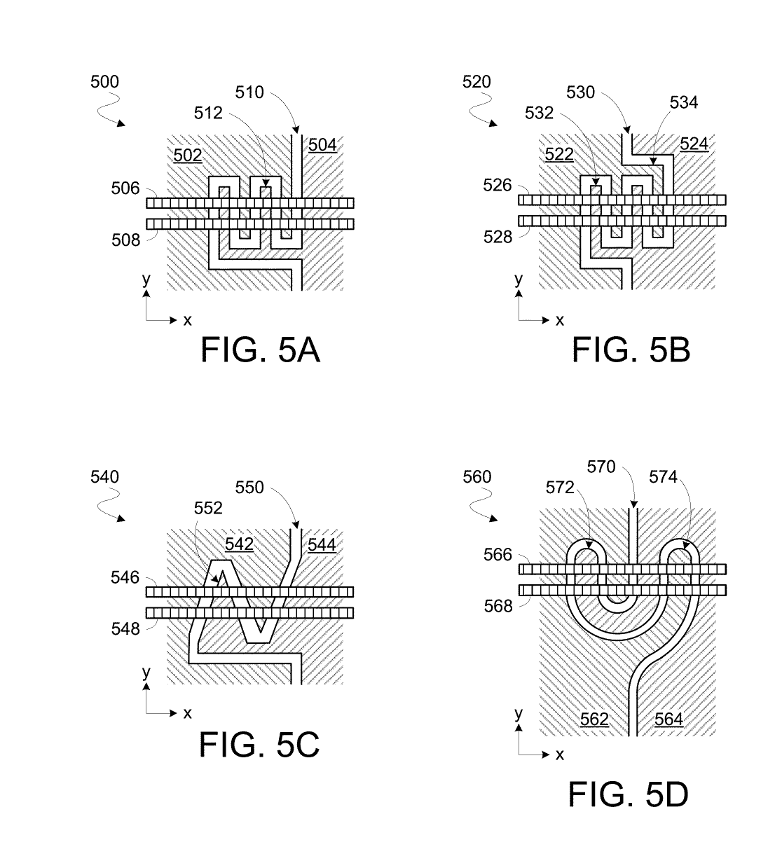

FIG. 5A illustrates elements of a device 500 including structures to mitigate signal noise according to another embodiment. Device 500 may include some or all of the features of system 100, for example. Device 500 may include rails 502, 504 and traces 506, 508 that extend across a region 510 separating rails 502, 504 from one another. A branch portion 512 of rail 504 may extend along an x-axis direction toward rail 502 and at least partially into a groove formed by a side of rail 502 that adjoins region 510. Branch portion 512 may include a primary branch sub-portion and multiple secondary branch sub-portions that each extend on a same side of the primary branch sub-portion. The groove of rail 502 in which branch portion 512 is disposed may conform at least in part to some or all edges of branch portion 512. As a result, respective portions of rails 502, 504 may be interleaved with one another—e.g., along the x-axis shown.

FIG. 5B illustrates elements of a device 520 including structures to mitigate signal noise according to another embodiment. Device 520 may include some or all of the features of system 100, for example. Device 520 may include rails 522, 524 and traces 526, 528 that extend across a region 530 separating rails 522, 524 from one another. A branch portion 532 of rail 524 may extend along an x-axis direction toward rail 522 and at least partially into a groove formed by a side of rail 522 that adjoins region 530. Additionally or alternatively, a branch portion 534 of rail 522 may extend along another x-axis direction toward rail 524 and at least partially into a groove formed by a side of rail 524 that adjoins region 530.

FIG. 5C illustrates elements of a device 540 including structures to mitigate signal noise according to another embodiment. Device 540 may include some or all of the features of system 100, for example. Device 540 may include rails 542, 544 and traces 546, 548 that extend across a region 550 separating rails 542, 544 from one another. A branch portion 552 of rail 544 may extend along an x-axis direction toward rail 542 and at least partially into a groove formed by a side of rail 542 that adjoins region 550. The branch portion 552 may include a primary branch sub-portion and any of a variety of one or more geometric shapes extending from the primary branch sub-portion—e.g., as demonstrated by the illustrative triangular shape shown. The groove of rail 542 in which branch portion 552 is disposed may conform at least in part to some or all edges of branch portion 552.

FIG. 5D illustrates elements of a device 560 including structures to mitigate signal noise according to another embodiment. Device 560 may include some or all of the features of system 100, for example. Device 560 may include rails 562, 564 and traces 566, 568 that extend across a region 570 separating rails 562, 564 from one another. A curved branch portion 572 of rail 564 may extend at least partially into a groove formed by a side of rail 562 that adjoins region 570. Additionally or alternatively, a curved branch portion 574 of rail 562 may extend at least partially into a groove formed by a side of rail 564 that adjoins region 570.

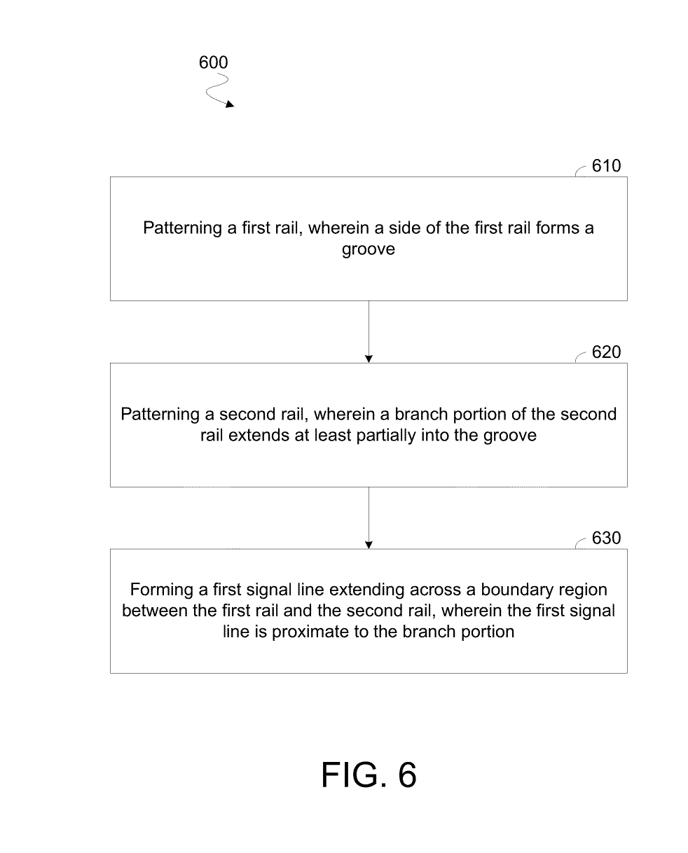

FIG. 6 illustrates elements of a method 600 of fabricating a device including structures to mitigate signal noise according to an embodiment. Performance of method 600 may include fabricating at least in part a PCB or packaged IC device, for example. The device may include some or all of the features of system 100—e.g., wherein the device has an arrangement of one or more branch and groove structures having features discussed herein.

In an embodiment, method 600 comprises, at 610, patterning a first rail (e.g., rail 110) of the device, wherein a side of the first rail forms a first groove. The patterning the first rail at 610 may include disposing a pattern of copper and/or other conductive material directly or indirectly onto a substrate layer. In one embodiment, the substrate layer is provided to serve as a PCB substrate. For example, the substrate layer may include any of a variety of plastic, glass (e.g., fiberglass), or other electrically insulative materials used in conventional PCBs. In another embodiment, the substrate layer is to serve as a semiconductor substrate for an IC chip. For example, the substrate material may include any of a variety of silicon substrate materials having integrated circuit structures formed therein and/or thereon—e.g., wherein the first rail is patterned on an insulative material (such as silicon nitride) disposed directly or indirectly on such a semiconductor substrate.

Method 600 may further comprise, at 620, patterning a second rail (e.g., rail 112) of the device, wherein a branch portion of the second rail extends at least partially into the groove formed by the side of the first rail. By way of illustration and not limitation, a patterned side of the second rail may bend, curve or otherwise extend in a direction toward the groove to form the branch portion. A boundary region between the first rail and the second rail may comprise an insulator material—e.g. the same as an insulator material of the substrate layer—that adjoins both the branch portion and a portion of the side of the first rail that forms the groove.

The patterning of the first rail at 610 and/or the patterning of the second rail at 620 may include one or more operations adapted from any of various conventional mask, photoresist, etch and/or other techniques for forming a conductive trace, sheet or other such structure that is to serve as a rail to provide a potential (e.g., a supply voltage or a reference voltage) to one or more components. These conventional techniques may include any of various operations to fabricate such structures on a PCB, or any of various operations to fabricate such structures in or on an IC chip. Such conventional techniques are not detailed herein to avoid obscuring features of certain embodiments.

Method 600 may further comprise, at 630, forming a first signal line extending across a boundary region between the first rail and the second rail, wherein the first signal line is proximate to the branch portion. In the context of distance between a signal line and a branch portion, “proximate” herein refers to a minimum distance between a branch portion and a signal line being less than twice a maximum width (e.g., measured along one of the y-axes variously shown herein) of a groove in which the branch portion is disposed.

The formation of the first signal line at 630 may include one or more operations adapted from conventional mask, photoresist, etch and/or other techniques—e.g., where such conventional techniques are also adapted to perform at least part of the patterning at 610 and/or 620. In some embodiments, such operations further comprise forming a second signal line extending across the boundary region, where (like the first signal line) at least part of the second signal line is proximate to the branch portion. The first rail and the second rail may each be configured to provide a respective potential at least in part along a first layer (e.g., a metallization layer) in which the groove and the branch portion are formed. In such an embodiment, the first signal line (and, in some embodiments, a second line) may be formed to communicate a signal through a plane that is orthogonal to the first layer and that extends through at least part of the boundary region.

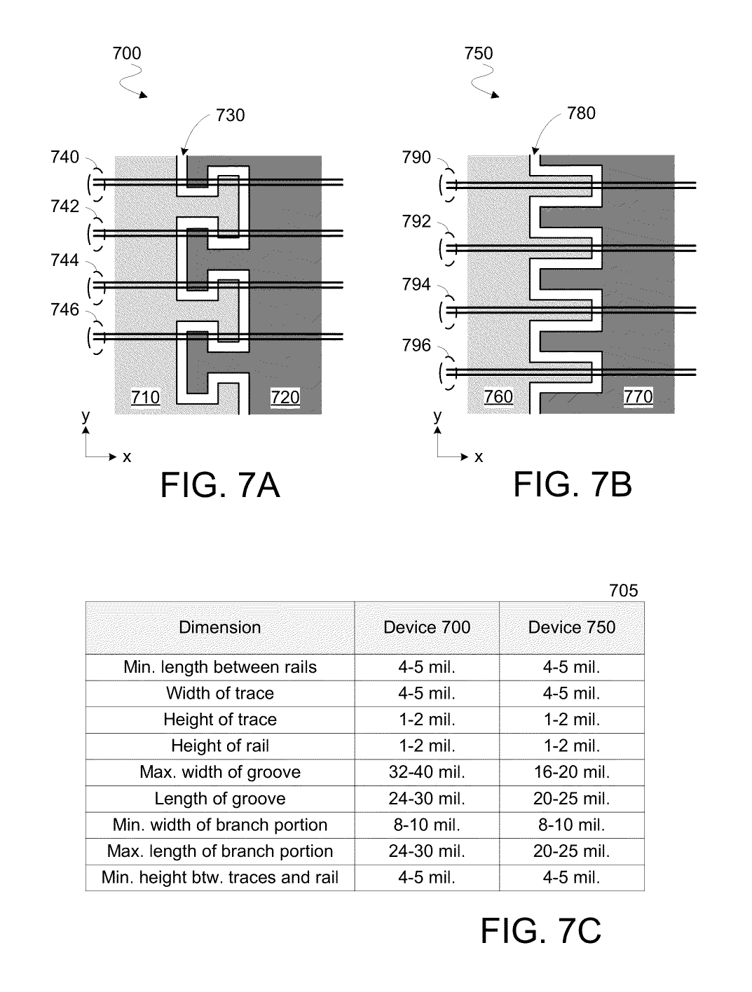

FIG. 7A illustrates elements of a device 700 including a split plane arrangement of rails 710, 720 and pairs 740, 742, 744, 746 of signal lines each to variously exchange respective signals (e.g. of a respective differential signal pair) across a plane that is both orthogonal to a layer including rails 710, 720 and extends through at least part of a boundary region 730 between rails 710, 720. Device may include some or all of the features of system 100—e.g., where some or all of device 700 is fabricated by method 600.

Rails 710, 720 may variously form multiple groove structures and multiple branch structures each corresponding to (e.g. extending at least partially into) a respective one of the multiple groove structures. By way of illustration and not limitation, a T-shape branch structure and a corresponding T-shape groove structure of device 700 may include some or all of the features of an arrangement of branch-grove structures such as that shown for device 340 and/or device 360. It is noted that, in some embodiments, either one of rails 710, 720 may be considered as providing a groove shape, where the other of rails 710, 720 thus forms the corresponding branch portion disposed at least partially therein.

Signal pairs 740, 742, 744, 746 may variously exchange signals between different and/or the same components (not shown) that may be included in or coupled to device 700. Such signals may variously experience an impedance discontinuity near boundary region 730. As a matter of physics, energy must be conserved at these impedance discontinuity boundaries. As a result, some signal energy may be reflected back towards a signal source driver, causing any of various signal integrity issues. Unwanted electromagnetic (EM) energy may also be radiated.

The T-shaped branch and groove structures of device 700 are one example of interleaved features that aid in increasing capacitance between rails 710, 720, resulting in relatively less signal noise generation. Certain embodiments provide for significant (e.g., 3×) increases in capacitance between rails of a split plane configuration. The associated improvements in signal integrity are helpful in many use cases including, but not limited to, any of various bus types—such as Dual Data Rate 3 (DDR3)—that support multiple, high-speed point-to-point connections. Certain embodiments provide for this additional coupling capacitance merely by design—e.g., without requiring any additional discrete component. Therefore, increases to BOM costs may be avoided.

FIG. 7B illustrates elements of a device 750 including a split plane arrangements of rails 760, 770 and pairs 790, 792, 794, 796 of signal lines each to variously exchange respective signals (e.g. of a respective differential signal pair) across a plane orthogonal to a layer including rails 760, 770 and extending through part of a boundary region 780 between rails 760, 770. Device 750 may include one or more features of device 700, for example.

For example, rails 760, 770 may variously form multiple groove structures and corresponding multiple branch structures to variously mitigate noise in signal line pairs 790, 792, 794, 796. In the illustrative embodiment of device 750, straight branch portions and corresponding straight groove portions are formed by sides of rails 760, 770. It is noted that, in some embodiments, either one of rails 760, 770 may be considered as providing a groove shape, where the other of rails 760, 770 thus forms the corresponding branch portion disposed at least partially therein.

FIG. 7C shows a table 705 listing examples of dimensions for device 700 and 750. In table 705, length dimensions refer to measurements along the x-axes variously shown in FIGS. 7A, 7B, width dimensions refer to measurements along the y-axes variously shown in FIGS. 7A, 7B, and height dimensions refer to measurements along a z-axis (not shown) that is orthogonal both an x-axis and y-axis. The x-axes and y-axes discussed herein are merely provided for reference in discussing features of certain embodiments. In various embodiments, a single rail of a device may include multiple branch structures and/or groove structures that have different respective orientations to mitigate noise in signal lines that are to carry respective signals along various directions.

The values of table 705 are merely illustrative of certain embodiments, and may vary significantly in other embodiments—e.g., according to implementation specific details. For example, table 705 may represent dimensions of structures formed in or on a printed circuit board. However, certain embodiments may be variously scaled down to dimensions such as those of components in a packaged IC device. Furthermore, it is noted that the various representations of branch structures and groove structures herein are not necessarily to scale with some embodiments.

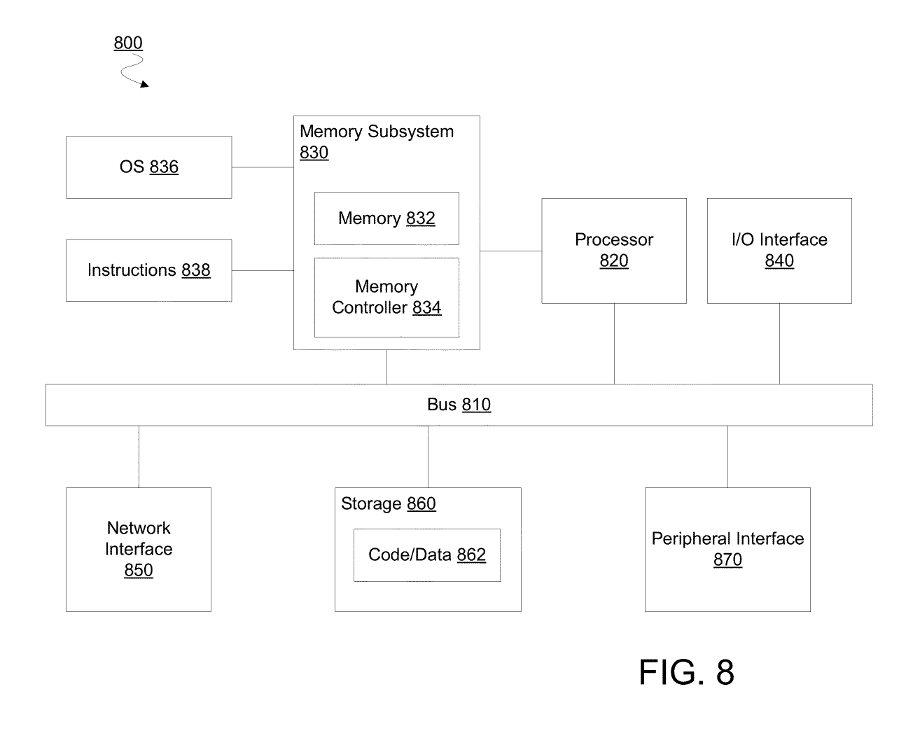

FIG. 8 is a block diagram of an embodiment of a computing system in which signal noise mitigation may be implemented. System 800 represents a computing device in accordance with any embodiment described herein, and may be a laptop computer, a desktop computer, a server, a gaming or entertainment control system, a scanner, copier, printer, or other electronic device. System 800 may include processor 820, which provides processing, operation management, and execution of instructions for system 800. Processor 820 may include any type of microprocessor, central processing unit (CPU), processing core, or other processing hardware to provide processing for system 800. Processor 820 controls the overall operation of system 800, and may be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 830 represents the main memory of system 800, and provides temporary storage for code to be executed by processor 820, or data values to be used in executing a routine. Memory subsystem 830 may include one or more memory devices such as read-only memory (ROM), flash memory, one or more varieties of random access memory (RAM), or other memory devices, or a combination of such devices. Memory subsystem 830 stores and hosts, among other things, operating system (OS) 836 to provide a software platform for execution of instructions in system 800. Additionally, other instructions 838 are stored and executed from memory subsystem 830 to provide the logic and the processing of system 800. OS 836 and instructions 838 are executed by processor 820.

Memory subsystem 830 may include memory device 832 where it stores data, instructions, programs, or other items. In one embodiment, memory subsystem includes memory controller 834, which is a memory controller in accordance with any embodiment described herein, and which provides mechanisms for monitoring performance of memory device 832. In one embodiment, memory controller 834 provides commands to memory device 832. The commands may be for memory device 832 to access data—e.g., on behalf of processor 820.

Processor 820 and memory subsystem 830 are coupled to bus/bus system 810. Bus 810 is an abstraction that represents any one or more separate physical buses, communication lines/interfaces, and/or point-to-point connections, connected by appropriate bridges, adapters, and/or controllers. Therefore, bus 810 may include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 810 may also correspond to interfaces in network interface 850.

System 800 may also include one or more input/output (I/O) interface(s) 840, network interface 850, one or more internal mass storage device(s) 860, and peripheral interface 870 coupled to bus 810. I/O interface 840 may include one or more interface components through which a user interacts with system 800 (e.g., video, audio, and/or alphanumeric interfacing). Network interface 850 provides system 800 the ability to communicate with remote devices (e.g., servers, other computing devices) over one or more networks. Network interface 850 may include an Ethernet adapter, wireless interconnection components, USB (universal serial bus), or other wired or wireless standards-based or proprietary interfaces.

Storage 860 may be or include any conventional medium for storing large amounts of data in a nonvolatile manner, such as one or more magnetic, solid state, or optical based disks, or a combination. Storage 860 holds code or instructions and data 862 in a persistent state (i.e., the value is retained despite interruption of power to system 800). Storage 860 may be generically considered to be a “memory,” although memory 830 is the executing or operating memory to provide instructions to processor 820. Whereas storage 860 is nonvolatile, memory 830 may include volatile memory (i.e., the value or state of the data is indeterminate if power is interrupted to system 800).

Peripheral interface 870 may include any hardware interface not specifically mentioned above. Peripherals refer generally to devices that connect dependently to system 800. A dependent connection is one where system 800 provides the software and/or hardware platform on which operation executes, and with which a user interacts.

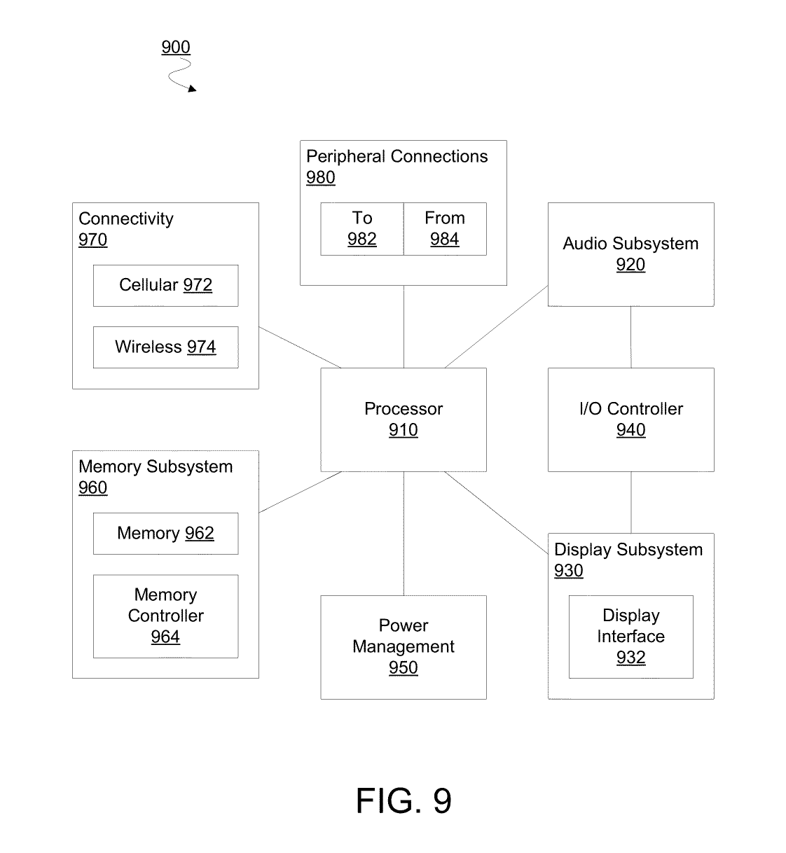

FIG. 9 is a block diagram of an embodiment of a mobile device in which signal noise mitigation may be implemented. Device 900 represents a mobile computing device, such as a computing tablet, a mobile phone or smartphone, a wireless-enabled e-reader, or other mobile device. It will be understood that certain of the components are shown generally, and not all components of such a device are shown in device 900.

Device 900 may include processor 910, which performs the primary processing operations of device 900. Processor 910 may include one or more physical devices, such as microprocessors, application processors, microcontrollers, programmable logic devices, or other processing means. The processing operations performed by processor 910 include the execution of an operating platform or operating system on which applications and/or device functions are executed. The processing operations include operations related to I/O (input/output) with a human user or with other devices, operations related to power management, and/or operations related to connecting device 900 to another device. The processing operations may also include operations related to audio I/O and/or display I/O.

In one embodiment, device 900 includes audio subsystem 920, which represents hardware (e.g., audio hardware and audio circuits) and software (e.g., drivers, codecs) components associated with providing audio functions to the computing device. Audio functions may include speaker and/or headphone output, as well as microphone input. Devices for such functions may be integrated into device 900, or connected to device 900. In one embodiment, a user interacts with device 900 by providing audio commands that are received and processed by processor 910.

Display subsystem 930 represents hardware (e.g., display devices) and software (e.g., drivers) components that provide a visual and/or tactile display for a user to interact with the computing device. Display subsystem 930 may include display interface 932, which may include the particular screen or hardware device used to provide a display to a user. In one embodiment, display interface 932 includes logic separate from processor 910 to perform at least some processing related to the display. In one embodiment, display subsystem 930 includes a touchscreen device that provides both output and input to a user.

I/O controller 940 represents hardware devices and software components related to interaction with a user. I/O controller 940 may operate to manage hardware that is part of audio subsystem 920 and/or display subsystem 930. Additionally, I/O controller 940 illustrates a connection point for additional devices that connect to device 900 through which a user might interact with the system. For example, devices that may be attached to device 900 might include microphone devices, speaker or stereo systems, video systems or other display device, keyboard or keypad devices, or other I/O devices for use with specific applications such as card readers or other devices.

As mentioned above, I/O controller 940 may interact with audio subsystem 920 and/or display subsystem 930. For example, input through a microphone or other audio device may provide input or commands for one or more applications or functions of device 900. Additionally, audio output may be provided instead of or in addition to display output. In another example, if display subsystem includes a touchscreen, the display device also acts as an input device, which may be at least partially managed by I/O controller 940. There may also be additional buttons or switches on device 900 to provide I/O functions managed by I/O controller 940.

In one embodiment, I/O controller 940 manages devices such as accelerometers, cameras, light sensors or other environmental sensors, gyroscopes, global positioning system (GPS), or other hardware that may be included in device 900. The input may be part of direct user interaction, as well as providing environmental input to the system to influence its operations (such as filtering for noise, adjusting displays for brightness detection, applying a flash for a camera, or other features).

In one embodiment, device 900 includes power management 950 that manages battery power usage, charging of the battery, and features related to power saving operation. Memory subsystem 960 may include memory device(s) 962 for storing information in device 900. Memory subsystem 960 may include nonvolatile (state does not change if power to the memory device is interrupted) and/or volatile (state is indeterminate if power to the memory device is interrupted) memory devices. Memory 960 may store application data, user data, music, photos, documents, or other data, as well as system data (whether long-term or temporary) related to the execution of the applications and functions of system 900.

In one embodiment, memory subsystem 960 includes memory controller 964 (which could also be considered part of the control of system 900, and could potentially be considered part of processor 910). Memory controller 964 monitors performance of memory 962. For example, memory controller 964 may issue a command for memory 962 to access data—e.g., on behalf of processor 910.

Connectivity 970 may include hardware devices (e.g., wireless and/or wired connectors and communication hardware) and software components (e.g., drivers, protocol stacks) to enable device 900 to communicate with external devices. The device could be separate devices, such as other computing devices, wireless access points or base stations, as well as peripherals such as headsets, printers, or other devices.

Connectivity 970 may include multiple different types of connectivity. To generalize, device 900 is illustrated with cellular connectivity 972 and wireless connectivity 974. Cellular connectivity 972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 974 refers to wireless connectivity that is not cellular, and may include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 980 include hardware interfaces and connectors, as well as software components (e.g., drivers, protocol stacks) to make peripheral connections. It will be understood that device 900 could both be a peripheral device (“to” 982) to other computing devices, as well as have peripheral devices (“from” 984) connected to it. Device 900 commonly has a “docking” connector to connect to other computing devices for purposes such as managing (e.g., downloading and/or uploading, changing, synchronizing) content on device 900. Additionally, a docking connector may allow device 900 to connect to certain peripherals that allow device 900 to control content output, for example, to audiovisual or other systems.

In addition to a proprietary docking connector or other proprietary connection hardware, device 900 may make peripheral connections 980 via common or standards-based connectors. Common types may include a Universal Serial Bus (USB) connector (which may include any of a number of different hardware interfaces), DisplayPort including MiniDisplayPort (MDP), High Definition Multimedia Interface (HDMI), Firewire, or other type.

In one implementation, a device comprises a substrate layer, a first rail disposed on the substrate layer, wherein a side of the first rail forms a first groove, and a second rail disposed on the substrate layer, wherein a side of the second rail forms a first branch portion that extends at least partially into the first groove. The device further comprises a first signal line extending across a boundary region between the first rail and the second rail, the first signal line configured to communicate a first signal while the first rail is maintained at a first voltage and while the second rail is maintained at a second voltage, wherein a portion of the first signal line is proximate to the first branch portion. In an embodiment, the first branch portion includes a rectilinear or curved T-shape structure. In another embodiment, the first branch portion includes a rectilinear or curved L-shape structure. In another embodiment, the first branch portion includes a rectilinear or curved spiral structure.

In another embodiment, the device further comprises a second signal line extending across the boundary region, the second signal line configured to communicate a second signal while the first rail is maintained at the first voltage and while the second rail is maintained at the second voltage, wherein a portion of the second signal line is proximate to the first branch portion. In another embodiment, the device further comprises a third signal line and a fourth signal line each extending across the boundary region, the third signal line and a fourth signal line each configured to communicate a respective signal while the first rail is maintained at the first voltage and while the second rail is maintained at the second voltage, wherein a portion of the third signal and a portion of the fourth signal line are each proximate to the first branch portion.

In another embodiment, the side of the first rail further forms a second groove, wherein a second branch portion of the second rail extends at least partially into the second groove, where the device further comprises a third signal line extending across the boundary region, the third signal line to communicate a third signal while the first rail is maintained at the first voltage and while the second rail is maintained at the second voltage, wherein a portion of the third signal line is proximate to the second branch portion. In another embodiment, the device further comprises a fourth signal line extending across the boundary region, the fourth signal line to communicate a fourth signal while the first rail is maintained at the first voltage and while the second rail is maintained at the second voltage, wherein a portion of the fourth signal line is proximate to the second branch portion.

In another embodiment, the side of the first rail forms a second branch portion, wherein the side of the second rail forms a second groove portion, and wherein the second branch portion extends at least partially into the second groove. In another embodiment, a portion of the first signal line is proximate to the second branch portion. In another embodiment, the device further comprises a second signal line extending across the boundary region, the second signal line to communicate a second signal while the first rail is maintained at the first voltage and while the second rail is maintained at the second voltage, wherein a portion of the second signal line is proximate to the second branch portion.

In another implementation, a method comprises patterning a first rail on a substrate layer, wherein a side of the first rail forms a first groove, patterning a second rail on the substrate layer, wherein a first branch portion of the second rail extends at least partially into the first groove, and forming a first signal line extending across a boundary region between the first rail and the second rail, wherein a portion of the first signal line is approximate to the first branch portion. In an embodiment, patterning the second rail includes patterning a rectilinear or curved T-shape structure of the first branch portion. In another embodiment, wherein patterning the second rail includes patterning a rectilinear or curved L-shape structure of the first branch portion. In another embodiment, patterning the second rail includes patterning a rectilinear or curved spiral structure of the first branch portion.

In another embodiment, the method further comprises forming a second signal line extending across the boundary region, wherein a portion of the second signal line is approximate to the first branch portion. In another embodiment, the method further comprises forming a third signal line and a fourth signal line each extending across the boundary region, wherein a portion of the third signal and a portion of the fourth signal line are each proximate to the first branch portion. In another embodiment, the side of the first rail further forms a second groove, wherein a second branch portion of the second rail extends at least partially into the second groove, wherein the method further comprises forming a third signal line extending across the boundary region, wherein a portion of the third signal line is proximate to the second branch portion. In another embodiment, the method further comprises forming a fourth signal line extending across the boundary region, wherein a portion of the fourth signal line is proximate to the second branch portion. In another embodiment, the side of the first rail forms a second branch portion, wherein the side of the second rail forms a second groove portion, and wherein the second branch portion extends at least partially into the second groove. In another embodiment, a portion of the first signal line is proximate to the second branch portion. In another embodiment, the method further comprises forming a second signal line extending across the boundary region, wherein a portion of the second signal line is proximate to the second branch portion.

In another implementation, a system comprises a source device including circuitry configured to send a first signal, a sink device including circuitry configured to receive the first signal, a substrate layer, a first rail disposed on the substrate layer, wherein a side of the first rail forms a first groove, and a second rail disposed on the substrate layer, wherein a side of the second rail forms a first branch portion that extends at least partially into the first groove. The system further comprises a first signal line extending across a boundary region between the first rail and the second rail, the first signal line configured to communicate a first signal while the first rail is maintained at a first voltage and while the second rail is maintained at a second voltage, wherein a portion of the first signal line is proximate to the first branch portion. The system further comprises a display device coupled to the sink device, the display device to display an image based on the first signal.

In an embodiment, the first branch portion includes a rectilinear or curved T-shape structure. In another embodiment, the first branch portion includes a rectilinear or curved L-shape structure. In another embodiment, the first branch portion includes a rectilinear or curved spiral structure. In another embodiment, the system further comprises a second signal line extending across the boundary region, the second signal line to communicate a second signal while the first rail is maintained at the first voltage and while the second rail is maintained at the second voltage, wherein a portion of the second signal line is proximate to the first branch portion. In another embodiment, the system further comprises a third signal line and a fourth signal line each extending across the boundary region, the third signal line and a fourth signal line each to communicate a respective signal while the first rail is maintained at the first voltage and while the second rail is maintained at the second voltage, wherein a portion of the third signal and a portion of the fourth signal line are each proximate to the first branch portion.

In another embodiment, the side of the first rail further forms a second groove, wherein a second branch portion of the second rail extends at least partially into the second groove, and the system further comprises a third signal line extending across the boundary region, the third signal line to communicate a third signal while the first rail is maintained at the first voltage and while the second rail is maintained at the second voltage, wherein a portion of the third signal line is proximate to the second branch portion. In another embodiment, the system further comprises a fourth signal line extending across the boundary region, the fourth signal line to communicate a fourth signal while the first rail is maintained at the first voltage and while the second rail is maintained at the second voltage, wherein a portion of the fourth signal line is proximate to the second branch portion. In another embodiment, the side of the first rail forms a second branch portion, wherein the side of the second rail forms a second groove portion, and wherein the second branch portion extends at least partially into the second groove. In another embodiment, a portion of the first signal line is proximate to the second branch portion. In another embodiment, the system further comprises a second signal line extending across the boundary region, the second signal line to communicate a second signal while the first rail is maintained at the first voltage and while the second rail is maintained at the second voltage, wherein a portion of the second signal line is proximate to the second branch portion.

Techniques and architectures for mitigating signal noise are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
a substrate layer;
a first rail disposed on the substrate layer, wherein a side of the first rail forms a first groove;
a second rail disposed on the substrate layer, wherein a side of the second rail forms a first branch portion that extends at least partially into the first groove; and
a first signal line extending across a boundary region between the first rail and the second rail, the first signal line configured to communicate a first signal while the first rail is maintained at a first voltage and while the second rail is maintained at a second voltage, wherein a portion of the first signal line is proximate to the first branch portion.

2. The device of claim 1, wherein the first branch portion includes a rectilinear or curved T-shape structure.

3. The device of claim 1, wherein the first branch portion includes a rectilinear or curved L-shape structure.

4. The device of claim 1, wherein the first branch portion includes a rectilinear or curved spiral structure.

5. The device of claim 1, further comprising a second signal line extending across the boundary region, the second signal line configured to communicate a second signal while the first rail is maintained at the first voltage and while the second rail is maintained at the second voltage, wherein a portion of the second signal line is proximate to the first branch portion.

6. The device of claim 5, further comprising:
a third signal line and a fourth signal line each extending across the boundary region, the third signal line and a fourth signal line each configured to communicate a respective signal while the first rail is maintained at the first voltage and while the second rail is maintained at the second voltage, wherein a portion of the third signal and a portion of the fourth signal line are each proximate to the first branch portion.

7. The device of claim 1, wherein the side of the first rail further forms a second groove, wherein a second branch portion of the second rail extends at least partially into the second groove, the device further comprising:
a third signal line extending across the boundary region, the third signal line to communicate a third signal while the first rail is maintained at the first voltage and while the second rail is maintained at the second voltage, wherein a portion of the third signal line is proximate to the second branch portion.

8. The device of claim 7, further comprising:
a fourth signal line extending across the boundary region, the fourth signal line to communicate a fourth signal while the first rail is maintained at the first voltage and while the second rail is maintained at the second voltage, wherein a portion of the fourth signal line is proximate to the second branch portion.

9. The device of claim 1, wherein the side of the first rail forms a second branch portion, wherein the side of the second rail forms a second groove portion, and wherein the second branch portion extends at least partially into the second groove.

10. The device of claim 9, wherein a portion of the first signal line is proximate to the second branch portion.

11. The device of claim 9, further comprising:
a second signal line extending across the boundary region, the second signal line to communicate a second signal while the first rail is maintained at the first voltage and while the second rail is maintained at the second voltage, wherein a portion of the second signal line is proximate to the second branch portion.

12. A method comprising:
patterning a first rail on a substrate layer, wherein a side of the first rail forms a first groove;
patterning a second rail on the substrate layer, wherein a first branch portion of the second rail extends at least partially into the first groove; and
forming a first signal line extending across a boundary region between the first rail and the second rail, wherein a portion of the first signal line is approximate to the first branch portion.

13. The method of claim 12, wherein patterning the second rail includes patterning a rectilinear or curved T-shape structure of the first branch portion.

14. The method of claim 12, wherein patterning the second rail includes patterning a rectilinear or curved L-shape structure of the first branch portion.

15. The method of claim 12, wherein patterning the second rail includes patterning a rectilinear or curved spiral structure of the first branch portion.

16. The method of claim 12, further comprising forming a second signal line extending across the boundary region, wherein a portion of the second signal line is approximate to the first branch portion.

17. The method of claim 16, further comprising:
forming a third signal line and a fourth signal line each extending across the boundary region, wherein a portion of the third signal and a portion of the fourth signal line are each proximate to the first branch portion.

18. The method of claim 12, wherein the side of the first rail further forms a second groove, wherein a second branch portion of the second rail extends at least partially into the second groove, the method further comprising:
forming a third signal line extending across the boundary region, wherein a portion of the third signal line is proximate to the second branch portion.

19. The method of claim 12, wherein the side of the first rail forms a second branch portion, wherein the side of the second rail forms a second groove portion, and wherein the second branch portion extends at least partially into the second groove.

20. The method of claim 19, wherein a portion of the first signal line is proximate to the second branch portion.

21. A system comprising:
a source device including circuitry configured to send a first signal;
a sink device including circuitry configured to receive the first signal;
a substrate layer;
a first rail disposed on the substrate layer, wherein a side of the first rail forms a first groove;
a second rail disposed on the substrate layer, wherein a side of the second rail forms a first branch portion that extends at least partially into the first groove; and
a first signal line extending across a boundary region between the first rail and the second rail, the first signal line configured to communicate a first signal while the first rail is maintained at a first voltage and while the second rail is maintained at a second voltage, wherein a portion of the first signal line is proximate to the first branch portion; and
a display device coupled to the sink device, the display device to display an image based on the first signal.

22. The system of claim 21, wherein the first branch portion includes a rectilinear or curved T-shape structure.

23. The system of claim 21, wherein the first branch portion includes a rectilinear or curved L-shape structure.

24. The system of claim 21, wherein the first branch portion includes a rectilinear or curved spiral structure.

25. The system of claim 21, further comprising a second signal line extending across the boundary region, the second signal line to communicate a second signal while the first rail is maintained at the first voltage and while the second rail is maintained at the second voltage, wherein a portion of the second signal line is proximate to the first branch portion.
